(19) United States
(12) Patent Application Publication
(10) Pub. No.: US 2012/0293791 A1
(43) Pub. Date: Nov. 22, 2012

(54) Sample Holder with Optical Features for Holding a Sample in an Analytical Device for Research Purposes

(75) Inventors: Mirko Milas, Baden (CH); Yimei Zhu, East Setauket, NY (US); Jonathan David Rameau, Middle Island, NY (US)

(73) Assignee: Brookhaven Science Associates, LLC, Upton, NY (US)

(21) Appl. No.: 13/479,330

(22) Filed: May 24, 2012

Related U.S. Application Data
(63) Continuation-in-part of application No. 13/398,623, filed on Feb. 16, 2012.
Application No. 13/398,623 is a continuation of application No. 12/582,149, filed on Oct. 20, 2009, now Pat. No. 8,143,593.
(60) Provisional application No. 61/106,637, filed on Oct. 20, 2008.

(51) Int. Cl. G01N 21/01; H01J 37/20

(52) U.S. Cl. 356/72

(57) ABSTRACT

A method for performing time resolved imaging, spectroscopy or diffraction techniques involving a sample held in an analytical device. The method generally includes supporting a sample within an analytical device with a sample holder, conveying a light beam through an internal conduit of a sample holder body of the sample holder and directing the light beam between the sample holder body and the sample with a first light beam positioner of a sample support member of the sample holder, such that the light beam and an energy pulse emitted by an energy source of the analytical device converge on the sample supported by the sample holder within the analytical device.

This application is a continuation-in-part of Ser. No. 13/398,623 filed on Feb. 16, 2012; which claims the benefit of U.S. application Ser. No. 12/582,149, filed on Oct. 20, 2009, now U.S. Pat. No. 8,143,593 issued Mar. 27, 2012, and U.S. Provisional Application No. 61/106,637, filed on Oct. 20, 2008, the specifications of which are incorporated by reference herein in their entirety for all purposes.

This invention was made with Government support under contract number DE-AC02-98CH10886, awarded by the U.S. Department of Energy. The Government has certain rights in the invention.

### BACKGROUND

The present sample holder is described herein for holding a sample to be observed for research purposes, and more particularly to a sample holder for holding a sample to be observed in an analytical device, such as an electron microscope, (e.g., a transmission electron microscope (IBM)), and which has the capability of delivering and accurately directing a light beam to the sample held by the sample holder and/or collect a light beam and transport it outside the analytical device for analysis.

Analytical instruments for observing and studying samples under certain prescribed conditions are well known in the art. For example, structural evaluation using an electron microscope has been conventionally employed as one of the methods for examining and evaluating samples in the fields of micro- and nanotechnology. The electron microscopes used in these fields mainly include the scanning electron microscopes (SEM) and the transmission electron microscopes (TEM). In the SEM, a beam of electrons is applied to a cleavage plane or an FIB (Focused Ion Beam) processed plane of the sample being observed (observed sample) and secondary electrons etc. obtained from the sample form an image for observation.

In the TEM, a beam of electrons is transmitted through a very thin, (e.g., 1 μm thick or less), observed sample and transmitted electrons and scattered electrons (e.g., elastically scattered electrons) form an image for observation of the internal structure of the sample. The image formed from the electrons transmitted through the specimen is typically magnified and focused by an objective lens and appears on an imaging screen, (i.e., a fluorescent screen in most TEMs), plus a monitor, or on a layer of photographic film, or to be detected by a sensor such as a CCD camera.

Modern TEMs are often equipped with specimen holders that allow the user to tilt the specimen to a range of angles in order to obtain specific diffraction conditions, and apertures placed above the specimen allow the user to select electrons that would otherwise be diffracted in a particular direction from entering the specimen. By carefully selecting the orientation of the sample, it is possible not just to determine the position of defects but also to determine the type of defect present. If the sample is orientated so that one particular plane is only slightly tilted away from the strongest diffracting angle (known as the Bragg Angle), any distortion of the crystal plane that locally tilts the plane to the Bragg angle will produce particularly strong contrast variations. However, defects that produce only displacement of atoms that do not tilt the crystal to the Bragg angle (i.e. displacements parallel to the crystal plane) will not produce strong contrast.

The TEM is used heavily in both material science/metallurgy and the biological sciences. In both cases the specimens must be very thin and able to withstand the high vacuum present inside the instrument. For biological specimens, the maximum specimen thickness is roughly 1 micrometer. To withstand the instrument vacuum, biological specimens are typically held at liquid nitrogen temperatures after embedding in vitreous ice, or fixated using a negative staining material such as uranyl acetate or by plastic embedding. Typical biological applications include tomographic reconstructions of small cells or thin sections of larger cells and 3-D reconstructions of individual molecules via Single Particle Reconstruction.

In material science/metallurgy the specimens tend to be naturally resistant to vacuum, but must be prepared as a thin foil, or etched so some portion of the specimen is thin enough for the beam to penetrate. Preparation techniques to obtain an electron transparent region include ion beam milling and wedge polishing. The focused ion beam (FIB) is a relatively new technique to prepare thin samples for TEM examination from larger specimens. Because the FIB can be used to micro-machine samples very precisely, it is possible to mill very thin membranes from a specific area of a sample, such as a semiconductor or metal. Materials that have dimensions small enough to be electron transparent. Such as powders or nanotubes, can be quickly produced by the deposition of a dilute sample containing the specimen onto support grids. The suspension is normally a volatile solvent, such as ethanol, ensuring that the solvent rapidly evaporates allowing a sample that can be rapidly analyzed.

In certain applications, analysis of a sample subjected to light is desirable. Specifically, it is often desirable to analyze the optical properties of a sample under light conditions within an analytical device, such as a TEM. In this regard, attempts have been made to modify conventional analytical instruments by providing a window to the instrument housing to allow light from an external source to enter the interior chamber of the instrument in the area of the sample. Thus, prior solutions have involved modifications of the instrument column to provide an optical path to the sample position. As can be appreciated, such solutions are very complicated and expensive and involve major modifications of the analytical device.

Accordingly, it would be desirable to provide a sample holder for use in an analytical device or instrument that also has the capability of accurately delivering a precise, predetermined light beam directly to a sample held by the holder in order to analyze the optical properties of the sample under light conditions within the analytical device.

### SUMMARY OF THE INVENTION

The present invention is a sample holder for holding a sample to be observed for research purposes, within an analytical device, such as a transmission electron microscope (TEM). The sample holder generally includes an external alignment part for directing a light beam in a predetermined beam direction, a sample holder body in optical communication with the external alignment part and a sample support member disposed at a distal end of the sample holder body opposite the external alignment part for holding a sample to be analyzed. The sample holder body defines an internal conduit for the light beam and the sample support member includes a light beam positioner for directing the light beam between the sample holder body and the sample held by the sample support member.

In a preferred embodiment, the sample support member further includes a second light beam positioner, wherein the first light beam positioner delivers the light beam from the sample holder body to the sample held by the sample support member and the second light beam positioner collects the light beam from the sample and delivers the light beam to the sample holder body.

Each of the first and second light positioners is preferably a light deflection assembly for deflecting the light beam to and/or from the sample held by the sample support member. The light deflection assembly preferably includes a mirror support, a mirror disposed at a distal end of the mirror support, a first adjustment mechanism provided at a proximal end of the mirror support opposite the mirror for positioning the mirror in a first direction, a second adjustment mechanism engaged with the mirror support for positioning the mirror in a second direction and a third adjustment mechanism engaged with the mirror support for positioning the mirror in a third direction.

The sample support member preferably has a U-shaped body including parallel legs joined by a cross member. The legs are fixed to the sample holder body and at least one of the legs has an axial bore communicating with the internal conduit of the sample holder body for conveying the light beam between the sample holder body and the sample. In this case, the leg having the axial bore also has a transverse window communicating with the axial bore in the leg, and the first light positioner is a light deflection assembly disposed in the axial bore of the leg adjacent the window for deflecting the light beam between the leg axial bore and the sample through the window.

The light beam can be conveyed through the sample holder body via one or more optical fibers disposed within the internal conduit of the sample holder body. Where optical fibers are used, the light beam positioner can be in the form of a support platform for retaining the optical fiber, wherein the support platform is adjustable with respect to the sample support member for directing the light beam to and/or from the sample.

The present invention further involves a method for providing light to a sample held by a sample holder within an analytical device. The method generally includes the steps of conveying a light beam through an internal conduit of a sample holder body of the sample holder, holding the sample at a distal end of the sample holder body with a sample support member fixed to the distal end of the sample holder body and directing the light beam between the sample holder body and the sample with a first light beam positioner of the sample support member.

In one embodiment of the method according to the present invention, the light beam travels from the sample holder body and is deflected by the first light positioner toward the sample. In this embodiment, the light beam may further be caused to travel from the sample and deflected back to the sample holder body by a second light positioner of the sample support member. Alternatively, the light beam may be made to travel from the sample and deflected by the first light positioner into the sample holder body.

The method may further include the step of directing a second light beam between the sample holder body and the sample with a second light positioner of the sample support member. Also, the light beam may be conveyed through the sample holder body via an optic fiber disposed within the internal conduit of the sample holder body.

In any case, the sample holder of the present invention is particularly suited for use in electron microscopes, such as a transmission electron microscope (TEM), a scanning electron microscope, a scanning tunneling microscope, optical microscopes, atomic force microscopes, helium ion microscopes, photoelectron microscopes, x-ray microscopes, and has the capability of delivering and accurately directing a light beam to the sample held by the sample holder.

However, the present sample holder can be used in a wide variety of other analytical procedures and experimental techniques. For example, the present sample holder can be used to perform time resolved imaging, spectroscopy or diffraction techniques involving a sample held in an analytical device. In this case, a present method generally includes supporting a sample within an analytical device with a sample holder, wherein the sample holder has a sample holder body extending within an interior of the analytical device and a sample support member disposed at a distal end of the sample holder body for supporting the sample. A first light beam is conveyed through an internal conduit of the sample holder body of the sample holder and is directed between the sample holder body and the sample with a first light beam positioner of the sample support member. At the same time, an energy pulse is directed at the sample, such that the first light beam and the energy pulse converge on the sample. The sample is then analyzed under conditions of the converging energy pulse and the first light beam.

In a preferred embodiment, the method further includes directing a second light beam at an energy source provided within the analytical device and emitting the energy pulse from the energy source in response to the energy source receiving the first light beam, wherein the energy pulse is directed at the sample held in the sample holder.

In one embodiment, the analytical device is a four-dimensional ultra-fast electron microscope and the energy source is an electron emitter. Time resolved imaging of the sample can be achieved by varying a time duration between the first light beam and the energy pulse. Stroboscopic time resolved imaging can also be achieved by repeating the steps of directing the first light beam at the sample and directing the energy pulse at the sample and analyzing the sample under the conditions of the repeating pulses.

The present method also includes retrofitting an analytical device to perform time resolved imaging; spectroscopy, or diffraction techniques involving a sample. In this case, the analytical device has an energy source for emitting an energy pulse at the sample, but the analytical device can be simply modified by providing a first access port in the analytical device for inserting a sample into the analytical device. The sample is provided on a sample holder, which is inserted in the first access port of the analytical device. An analyzer is provided for analyzing the sample under conditions of the energy pulse and a first light beam converging on the sample.

The sample holder has the features as described above. Specifically, the sample holder includes an external alignment part for directing the first light beam in a predetermined beam direction. The sample holder further includes a sample holder body in optical communication with the external alignment part and a sample support member disposed at a distal end of the sample holder body opposite the external alignment part for holding the sample to be analyzed. The sample holder body defines an internal conduit for conveying the first light beam and the sample support member includes a first light beam positioner for directing the first light beam between the sample holder body and a sample held by the sample support member.

In a preferred embodiment, the method for retrofitting further includes providing a second access port in the analytical device for providing optical access to the energy source from outside the analytical device. A second light beam source is positioned at the second access port for directing a second light beam at the energy source for exciting the energy source, thereby causing the energy source to emit the energy pulse.

A preferred form of the sample holder, as well as other embodiments, objects, features and advantages of this invention, will be apparent from the following detailed description of illustrative embodiments thereof, which is to be read in conjunction with the accompanying drawings.

### BRIEF DESCRIPTION OF THE DRAWINGS

FIG. 1 is a schematic cross-sectional view of a conventional transmission electron microscope (TEM) having a sample holder formed in accordance with the present invention inserted therein.

FIG. 2 is a top perspective view of the sample holder of the present invention.

FIG. 2a is a top perspective view of the sample holder of the present invention with a stand-off mounted between the sample holder body and the external alignment part.

FIG. 3 is a side view of the external alignment part of the sample holder shown in FIG. 2.

FIG. 4 is a front view of the external alignment part of the sample holder shown in FIGS. 2 and 3.

FIGS. 5a and 5b are top perspective views showing alternative embodiments of the interface between the sample holder body and the external alignment part.

FIG. 6 is an enlarged perspective view of the sample holder body and the sample support member of the sample holder shown in FIG. 2.

FIG. 7 is a cross-sectional view of the sample support member of the sample holder.

FIG. 7a is a cross-sectional view of the sample support member shown in FIG. 7 with two mirror assemblies.

FIG. 8 shows schematic representations of the alternative embodiments of the mirror arrangement contained within the tip of the sample holder.

FIG. 9 is a partial cross-sectional view of the sample holder support member modified according to an alternative embodiment of the present invention.

FIG. 10 is a partial cross-sectional view of the sample holder support member modified according to another alternative embodiment of the present invention.

FIGS. 11a and 11b are top perspective views of alternative embodiments of the sample support structure of the present invention.

FIG. 12 is a schematic cross-sectional view of an ultrafast electron microscope of the prior art.

FIG. 13 is a cross-sectional view of the present sample holder in use for performing time resolved imaging, spectroscopy or diffraction techniques involving a sample held in an analytical device.

### DETAILED DESCRIPTION OF THE PREFERRED EMBODIMENT

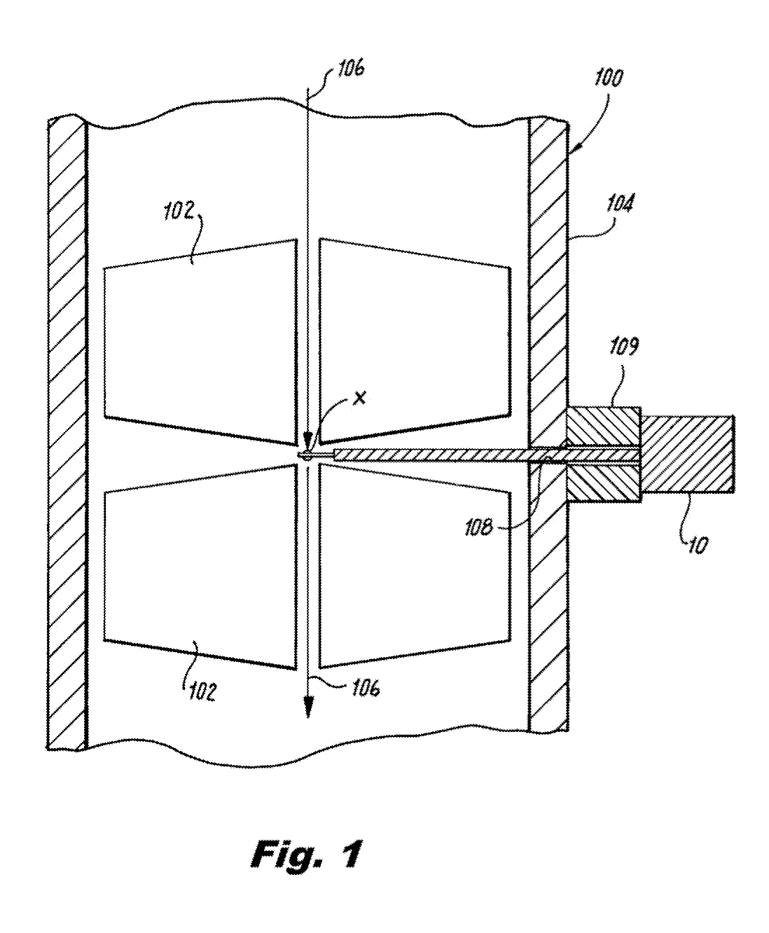

Referring first to FIG. 1, the sample holder 10 of the present invention is shown in schematic form in use with a conventional transmission electron microscope (TEM) 100. Although a TEM 100 is shown in FIG. 1, the present sample holder 10 is not limited to use in only a TEM. The present sample holder 10 is well suited for use in all analytical instruments or systems in which a vacuum compatible sample holder is utilized.

As is known in the art, the TEM typically includes an arrangement of electromagnetic lenses 102 contained within a housing 104 for directing and focusing a beam of electrons 106 through a sample X to be analyzed. Not shown in FIG. 1 is the source of electrons provided upstream of the sample X, or the detector provided downstream of the sample X for detecting the resultant interaction of the electrons with the sample.

The housing 104 of the TEM 100 typically further includes a portal 108 through which the sample holder 10 can be inserted to position the sample X within the electron beam path 106. A goniometer stage 109 is typically provided at the portal 108 to facilitate precise positioning of the sample 10. The goniometer stage 109 includes appropriate interfacial structure, such as O-rings and valves to maintain a vacuum inside the TEM housing 104 with the sample holder inserted therein. The goniometer stage 109 further includes adjustment mechanisms to finely position the sample holder 10 once it is in the beam path. It also provides one rotational degree of freedom (around the axis) that can tilt the sample.

As discussed above, conventional TEM sample holders typically consist of only a probe terminating at a tip and having means for supporting a sample at the end of the probe. Some sample holders, themselves, further include adjustment means for accurately positioning the sample within the TEM.

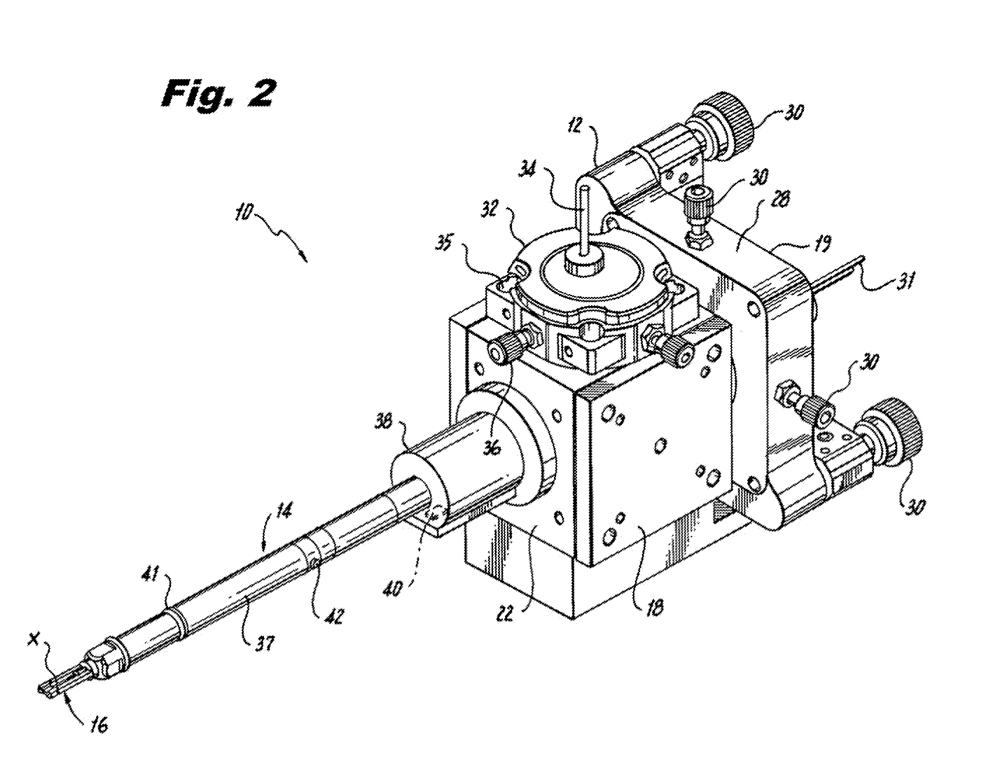

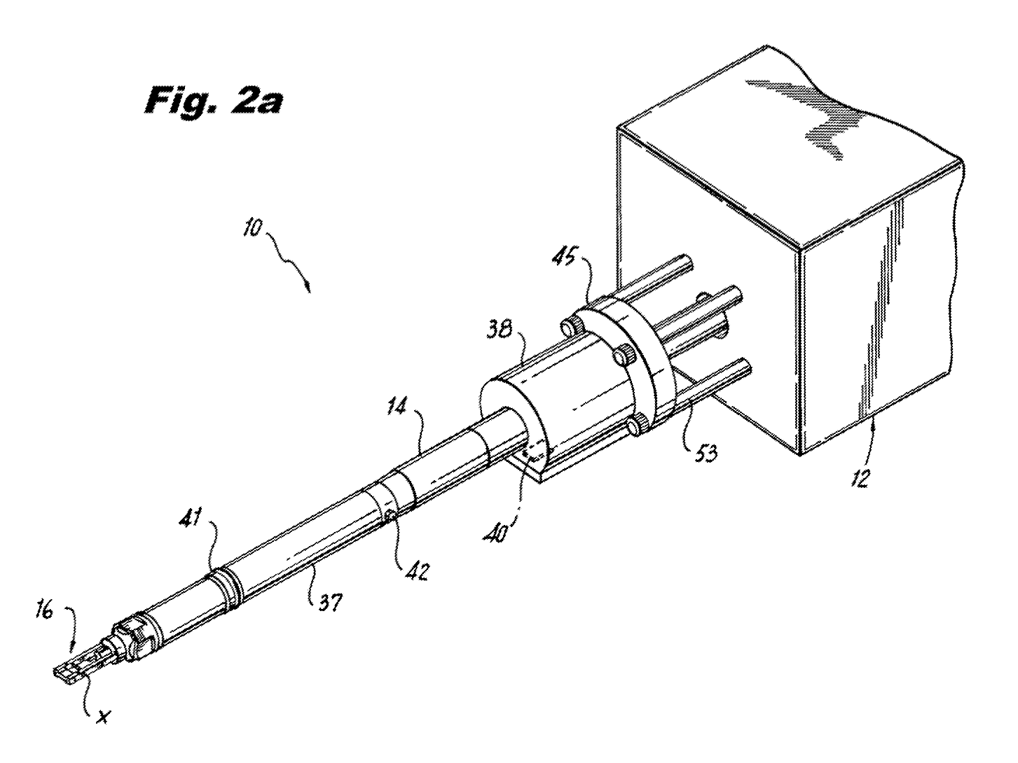

Turning now to FIG. 2, the sample holder 10 of the present invention is shown. The sample holder 10 generally includes an external alignment part 12, a sample holder body 14 extending out from the external alignment part and a sample support member 16 disposed at the end of the sample holder body opposite the external alignment part. In general, the external alignment part 12 is designed to accurately deliver a light beam into the sample holder body 14 and the sample support member 16 is designed to support a sample, while simultaneously directing the light beam to the sample. As will be discussed in further detail below, the sample support member 16 is further preferably designed to redirect the light beam back into the sample holder body 14 to be received by the external alignment part 12.

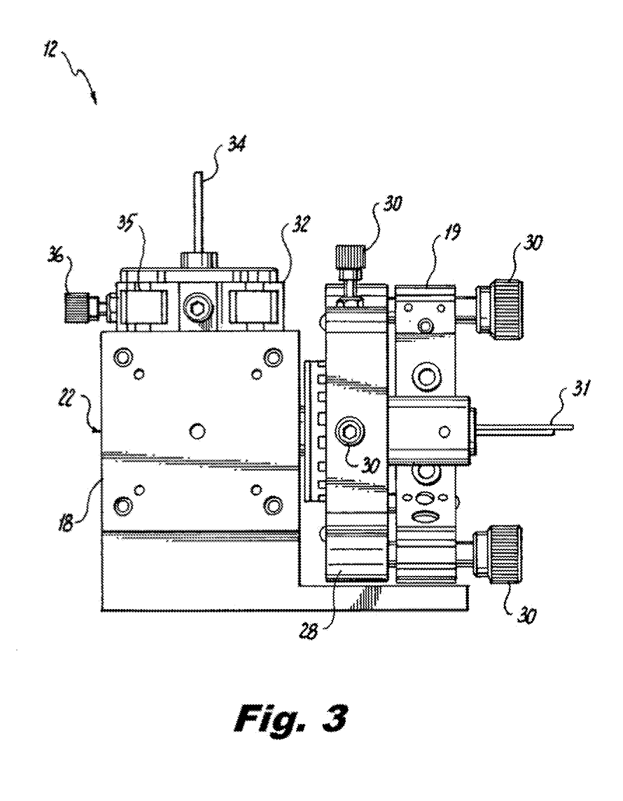

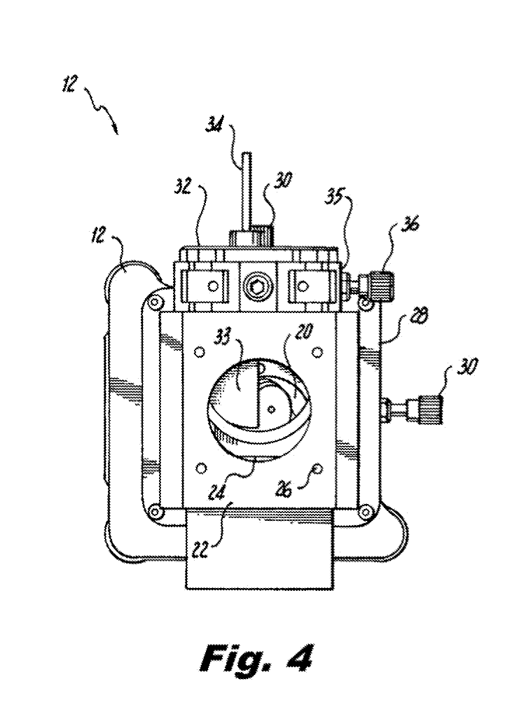

Referring additionally to FIGS. 3 and 4, the external alignment part 12 is adapted to interface with a light source, such as a laser (not shown) and is further preferably adapted to interface with a light detector (not shown). In this regard, the external alignment part 12 generally includes a housing 18 and a light source interface assembly 19 attached to one end of the housing. The housing 18 defines an interior 20, through which a light beam from a light source travels. The housing 18 further includes a sample holder body mounting surface 22 opposite the light source interface assembly 19 for mounting the sample holder body 14 thereto. The sample holder body mounting surface 22 has an opening 24 communicating with the interior 20 of the housing 18. The mounting surface 22 may also include apertures 26 to facilitate mounting of the sample holder body 14 to the mounting surface 22.

The light source interface assembly 19 is adapted to engage a light source and deliver a light beam from the light source into the interior 20 of the housing 18. The light source interface assembly 19 preferably includes a positioning stage 28 having adjustment and alignment mechanisms 30 with at least four degrees of freedom (two translations and two rotations) to accurately deliver a laser beam, for example, from the light source into the interior 20 of the housing 18. The light beam can be transmitted by an optical fiber 31, or can be directly emitted from a mounted laser source connected to the positioning stage 28 for accurately aiming and aligning the laser or highly collimated light beam into the sample holder body 14. The positioning stage 28 is preferably designed to accurately micro-position the light beam in the X, Y, and Z directions, plus three rotational degrees of freedom via the adjustment mechanisms 30.

As mentioned above, the external alignment part 12 is further preferably adapted to receive a returning light beam from the sample holder body 14 and direct the received light beam to a light detector optically connected to the external alignment part. As such, the external alignment part 12 further preferably includes a mirror 33 positioned within the interior 20 of the housing 18 to deflect a light beam received from the sample holder body 14 ninety degrees to a detector interface 32. The detector interface 32 is disposed on the housing 18 in a perpendicular fashion with respect to the light source interface 19 to receive the light beam deflected by the housing mirror 33. Like the light source interface 19, the detector interface 32 preferably includes an optical fiber 34 coupled to a focusing lens and connected to a positioning stage 35 capable of being aligned in two degrees of freedom (in-plane translation and one rotation) via an arrangement of adjustment mechanisms 36 for accurately aligning a received laser beam from the sample holder body 14.

In operation, a light beam from the light source is received by the light source interface 19 and is directed through the opening 24 of the sample holder body interface 22 into the sample holder body 14. The light beam travels the length of the sample holder body 14 and, as will be discussed in further detail below, is accurately delivered to a sample X held by the sample support member 16. As will be also discussed in further detail below, the sample support member 16 preferably reflects the beam back through the sample holder body 14 and back into the interior 20 of the external alignment part 12 through the opening 24 of the housing 18. The mirror 33 positioned within the interior 20 of the housing 18 deflects the returning light beam toward the detector interface 32, where the beam is collected and delivered to a detector for analysis.

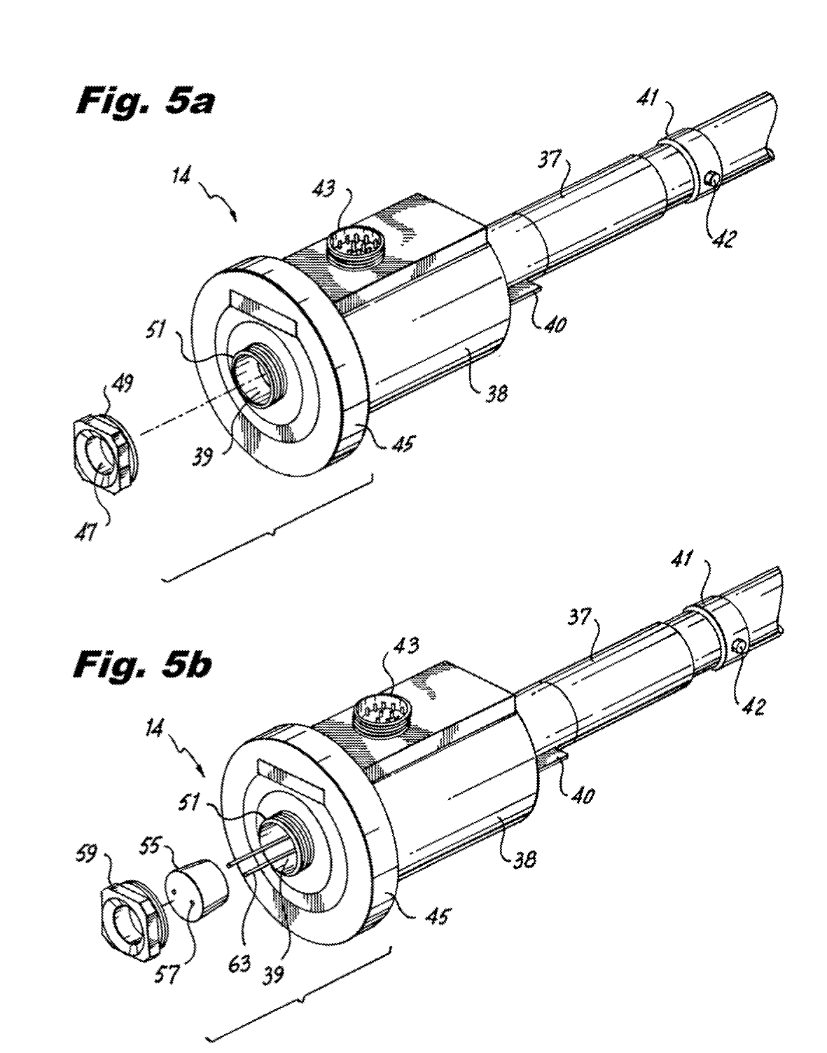

Thus, the sample holder body 14 essentially serves as a conduit for the light beam traveling between the external alignment part 12 and the sample support member 16. Referring now to FIGS. 5a and 5b, the sample holder body 14 is generally a tubular member and includes a probe portion 37 extending axially outward from a radially enlarged shoulder portion 38. The probe portion 37 and the shoulder portion 38 can be specifically designed and manufactured in terms of size and shape to be accommodated within the dimensions of a particular analytical device.

The probe portion 37 and the shoulder portion 38 can take the form of a hollow tube having a large singular central bore 39 extending the entire length of the sample holder body 14 to provide a clear optical path for the light beam. Such bore 39 can also be made large enough to accommodate one or more auxiliary devices, such as a STM tip, within the sample holder body 14, as will be discussed in further detail below. Alternatively, the probe portion 37 and the shoulder portion can be made more solid, whereby only two reduced diameter light beam conduits are formed axially therein.

The shoulder 38 of the sample holder body 14 is designed to engage an access portal of an analytical device, such as the portal 108 of the TEM housing 104 shown in FIG. 1. In this regard, the shoulder 38 may include one or more alignment tabs 40 to facilitate accurate positioning of the sample holder body within the device housing. Various O-ring seals 41 and additional alignment pins 42 may also be provided at select locations along the length of the probe portion 37 in order to respectively maintain a vacuum and align the probe portion within the analytical device when the sample holder 10 is inserted therein. The shoulder 38 may also include one or more electrical contacts 43 for providing electrical and/or data communication with an auxiliary device contained within the probe portion 37 of the sample holder body 14.

The bore 39 of the sample holder body 14 terminates at a proximal end 45 of the shoulder portion 38 opposite the probe portion 37. The proximal end 45 of the shoulder portion 38 is designed to be mounted to the sample holder body interface surface 22 of the external aligrunent part 12 so that the bore 39 of the sample holder body 14 is in optical communication with the interior 20 of the external alignment part housing 18.

The proximal end 45 of the shoulder portion 38 can be mounted directly to the sample holder body interface surface 22, as shown in FIG. 2, or a stand-off assembly 53 can be provided between the proximal end 45 of the shoulder portion 38 and the sample holder body interface surface 22 of the housing 18 so that a space is formed between the sample holder body 14 and the external alignment part 12, as shown in FIG. 2a. Such space may be desirable in certain applications for viewing and measuring the light beam as it passes between the external alignment part and the sample holder body. The stand-off assembly may simply consist of a plurality of spacer bars mounted between the proximal end 45 of the shoulder portion 38 and the sample holder body interface surface 22 of the housing 18.

In any event, it is preferable that a vacuum be maintained within the bore 39 of the sample holder body 14 when the body is mounted to the external alignment part 12. Accordingly, there are several options contemplated by the present invention for sealing the bore 39 from the environment while permitting a light beam to enter the bore.

In a preferred embodiment, as shown in FIG. 5a, a transparent window 47 is provided to seal the bore 39 yet allow a light beam to enter the bore of the sample holder body 14. The window 47, which can be made of glass or quartz, can be incorporated in an internally threaded cap 49, for example, which can be twisted on an externally threaded boss 51 formed on the proximal end 45 of the shoulder portion 38. An O-ring (not shown), or some other form of vacuum sealant, is further preferably provided between the internally threaded cap and the externally threaded boss 51 to facilitate a good vacuum connection therebetween. Such design allows a light beam to enter and exit the sample holder body 14 through the window while maintaining a vacuum within the bore 39.

In an alternative embodiment, as shown in FIG. 5b, optical fibers 63 are provided in the bore 39 of the sample holder body 14. In this design, the fibers 63 are fed through a ferrule 55 having passages 57 formed therein, for receiving the fibers in a sealing manner. The ferrule 57 is preferably made from Teflon and further has an outer diameter sized to seal the bore 39 of the sample holder body 14. The ferrule 57 can be retained in the bore 39 of the sample holder body 14 by an internally threaded cap 59, for example, which, again, can be twisted on an externally threaded boss 51 formed on the proximal end 45 of the shoulder portion 38. An example of an optical fiber coupling suitable for use with the present invention is shown and described in Abraham et al., “Teflon Feedthrough For Coupling Optical Fibers Into Ultrahigh Vacuum Systems,” Applied Optics, Vol. 37, No. 10, pp. 1762-1763 (Apr. 1, 1988), which is incorporated herein by reference in its entirety.

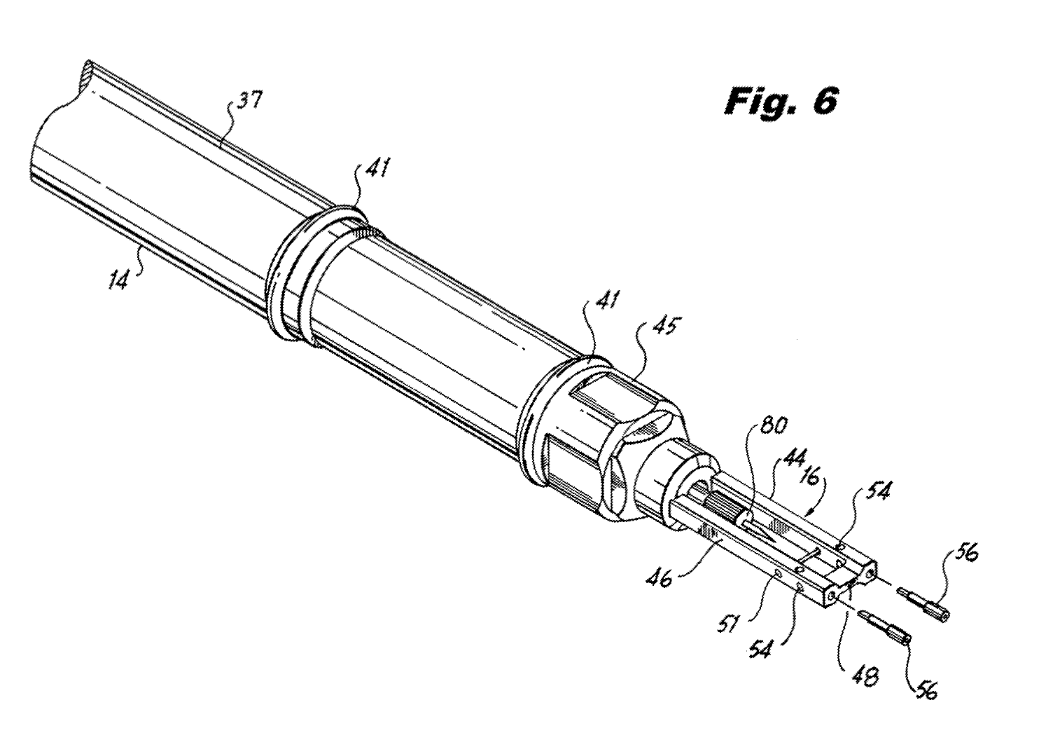

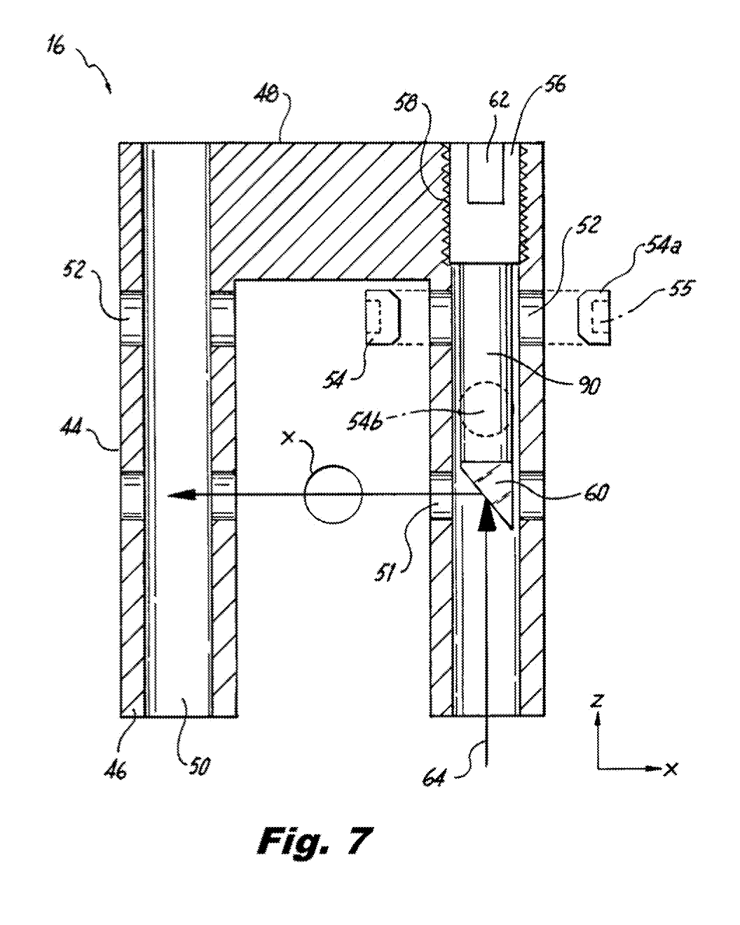

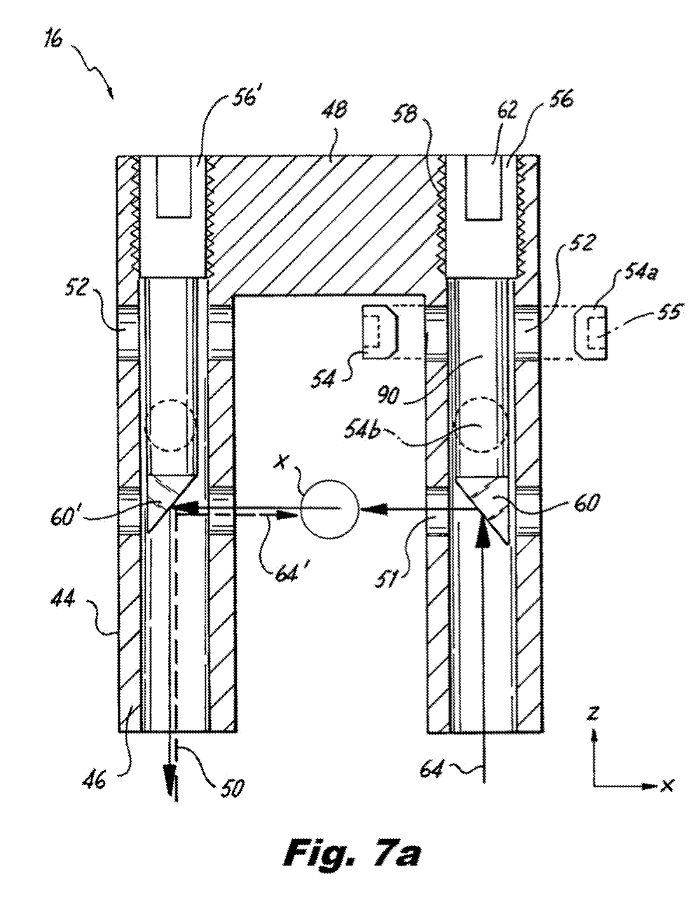

Turning now to FIGS. 6 and 7, disposed at the distal end of the sample holder body 14 opposite the shoulder portion 38, is the sample support member 16. The member 16 includes a U-shaped body 44 having parallel legs 46 joined by a cross member 48. The ends of the parallel legs 46 opposite the cross member 48 are fixed to the distal end of the sample holder body 14 and communicate with the axial bore 39 of the probe portion of the body. A fitting 45 of suitable design can be utilized to facilitate attachment of the U-shaped body 44 to the sample holder body 14.

In a preferred embodiment, each leg 46 of the U-shaped body 44 has a bore 50 formed therein. The bore 50 extends along the entire length of the leg 46 and communicates with the axial bore 39 of the sample holder body 14. Each leg 46 further preferably includes a pair of transverse optical windows 51 and a plurality of threaded transverse apertures 52 communicating with the central bore 50. The axial center line of the optical windows 51 and the threaded transverse apertures 52 are perpendicular to the axial center line of the leg axial bores 50. As will be discussed in further detail below, the optical windows 51 permit a light beam 64 to pass therethrough, and the transverse apertures 52 are internally threaded for engagement with external threads of alignment screws 54.

Received within at least one of the central bores 50 of the U-shaped member 44 is a light beam positioner 90 for directing the light beam from the sample holder body 14 to the sample X held by the sample support member 16. In a preferred embodiment, the light beam positioner 90 is a mirror assembly 56 including a mirror support 58, a mirror 60 provided at a distal end thereof, and a mirror adjustment screw 62 provided at a proximal end thereof opposite the mirror 60. In a preferred embodiment, two mirror assemblies 56 are provided for reflecting a light beam 64 back to the external alignment part 12, as will be discussed in further detail below.

The mirror 60 can be glued or otherwise fixed at the end of the mirror support 58. The mirror support 58 has a lateral width slightly smaller than the diameter of the leg bore 50 to allow for some adjustment of the position of the mirror support within the bore, as will be discussed in further detail below.

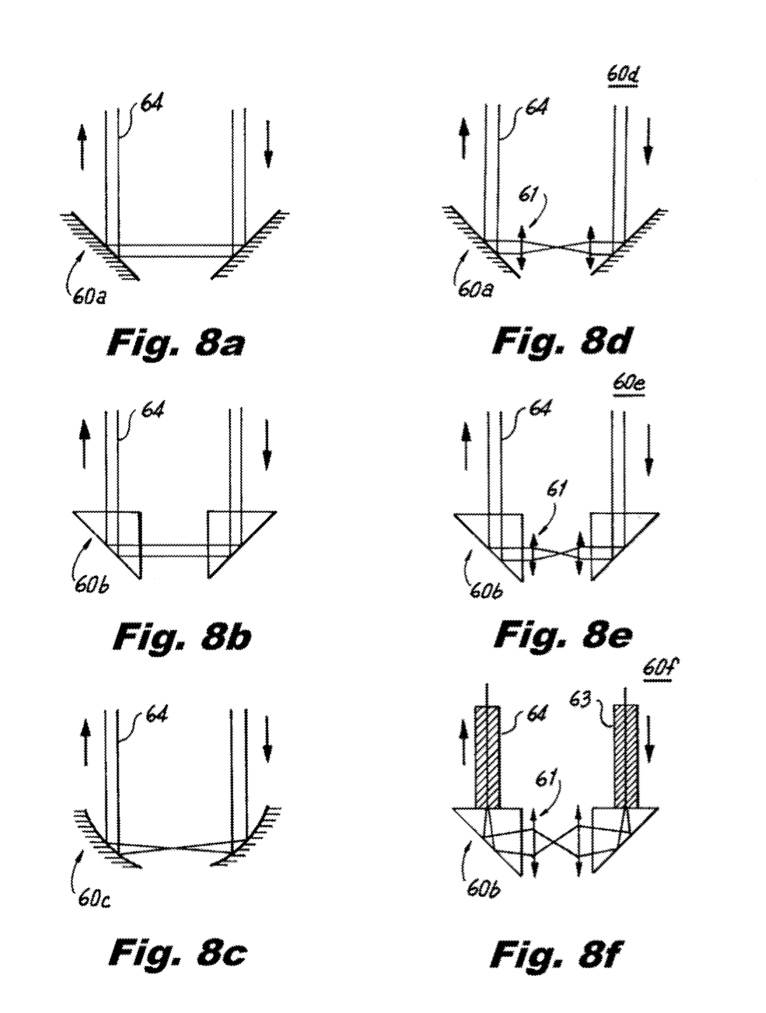

As used herein, the term “mirror” is intended to encompass any type of reflection or light deflection device. For example, the mirror 60 may include a flat mirror 60a, as shown in FIG. 8a, a reflection prism 60b, as shown in FIG. 8b, a parabolic mirror 60c, as shown in FIG. 8c, an arrangement of flat mirrors 60a and convex lenses 61, as shown in FIG. 8d, an arrangement of reflection prisms 60b and convex lenses 61, as shown in FIG. 8e or an arrangement of optical fibers 63 optically connected to reflection prisms 60b and including convex lenses 61, as shown in FIG. 8f.

In a preferred use, a mirror assembly 56 is provided in at least one of the bores 50 of the U-shaped member 44 for deflecting a light beam 64 traveling from the external alignment part 12 through the sample holder body 14 into the sample support member 16. The mirror 60 of the mirror assembly 56 is positioned to deflect the light beam 64 at a ninety (90) degree angle. The position of the mirror 60 is accurately adjusted by the adjustment screws 54. The alignment screws 54 are externally threaded and include a socket 55 for receiving a tool, such as an Allen key, for rotating the screw. Rotation of the screws 54 causes the screws to engage the outer surface of the mirror support 58 thereby urging the support member in a desired direction within the leg axial bore 50.

Preferably, there are four alignment screws 54 provided on the U-shaped member 44. Two alignment screws 54a are preferably provided for adjustment of the mirror assembly in the X-direction, as shown in FIG. 7, and two alignment screws 54b are provided for adjusting the mirror assembly in the Y-direction (perpendicular to the plane of the paper) as shown in FIG. 7. The mirror assembly 56 is further adjusted in the Z-direction by rotation of the mirror adjustment screw portion 62 of the mirror assembly. Thus, the mirror assembly 56 can be preciously adjusted to accurately receive the light beam 64 traveling along the central bore 50 of U-shaped member 44 and deflect the light beam ninety (90) degrees to exit through the transverse light beam aperture 51 to intersect with a sample X supported between the legs 44 of the U-shaped member.

As mentioned above, a second mirror assembly 56′ is preferably provided in the opposite leg 46 of the U-shaped member 44, as shown in FIG. 7a. The second mirror assembly 56′ can be utilized to receive the reflected light beam 64 from the first mirror assembly 56 and reflect the light beam an additional ninety (90) degrees so that the light beam returns up the sample body holder body 14 back to the external alignment part 12 for light detection purposes as discussed above.

Thus, the first aligning mirror 60 is positioned in the sample support member 16 so that it bends the beam 64 at the angle of ninety (90) degrees and traverses the area where the sample X will be fixed and continues to the area where a second aligning mirror 60′ will be positioned. The second aligning mirror 60′ is positioned in the sample support member 16 and aligned so that the beam 64 is deflected for another ninety (90) degrees and is aligned with the axis of the sample holder body 14 and falls on the mirror 38 in the external alignment part 12. Alignment of both the first and second mirrors is achieved using the five adjustment screws 54 and 62.

As described above, the beam 64 is deflected another ninety (90) degrees, within the external alignment part 12, and directed toward the lens collector system 32. Using the micropositioning device 36, the lens collector system 32 is aligned with the light beam 64 so that the collected light beam can be transported using the optical fiber 34 to a spectrometer (not shown).

Alternatively, the second mirror assembly 56′ can be provided in the U-shaped member to direct a second light beam 64′ traveling parallel to the first light beam 64 so that two light beams can be directed to the sample X supported between the legs 46 of the U-shaped member 44. In this case, two separate light beams originate in the external alignment part 12 and traverse the sample holder body 14, freely or via optical fibers, to be received by the mirrors 60 of the sample holder support member 16.

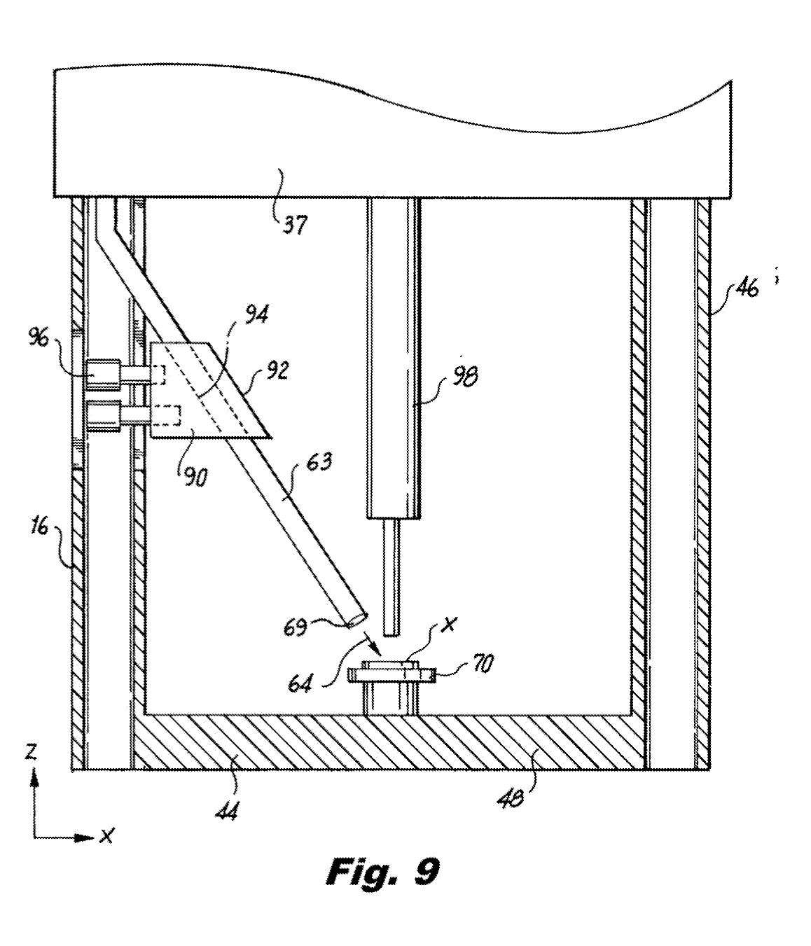

In an alternative embodiment, as shown in FIG. 9, the light positioner 90 can take the form of an adjustable fiber optic support platform 92. This embodiment is particularly suitable where an optical fiber 63 is used to convey the light beam 64 to the sample X. The fiber optic support platform 92 can be formed with a groove 94 to receive the optic fiber 63 exiting the sample holder body probe portion 37 and can include one or more adjustment screws 96 threadably connected thereto to permit adjustment of the platform 92 in the x, y and z directions. In this embodiment, the distance the light beam 64 travels to meet the sample is significantly reduced.

The sample holder 10 of the present invention can be used in combination with other research techniques commonly known in the field. For example, FIG. 9 also shows the sample support member 16 being used in conjunction with a thermal probe 98, typically used where heat dependent measurements are needed.

Similarly, the sample holder 10 of the present invention can also be adapted to provide scanning tunneling microscope (STM) capabilities in combination with optical measurement capabilities. Thus, as shown in FIG. 6, the sample holder body 14 can be designed to support a conventional STM tip 80 with the associated electrical wiring being contained within the probe portion 37 of the sample holder body. Thus, the invention can be adapted to integrate an optical system with a piezo-mechanical STM system in a single sample holder. As a result, the user can utilize the STM setup for positioning or for contacting the sample, and the optical part to illuminate the sample and/or collect the light emitted/scattered from the sample.

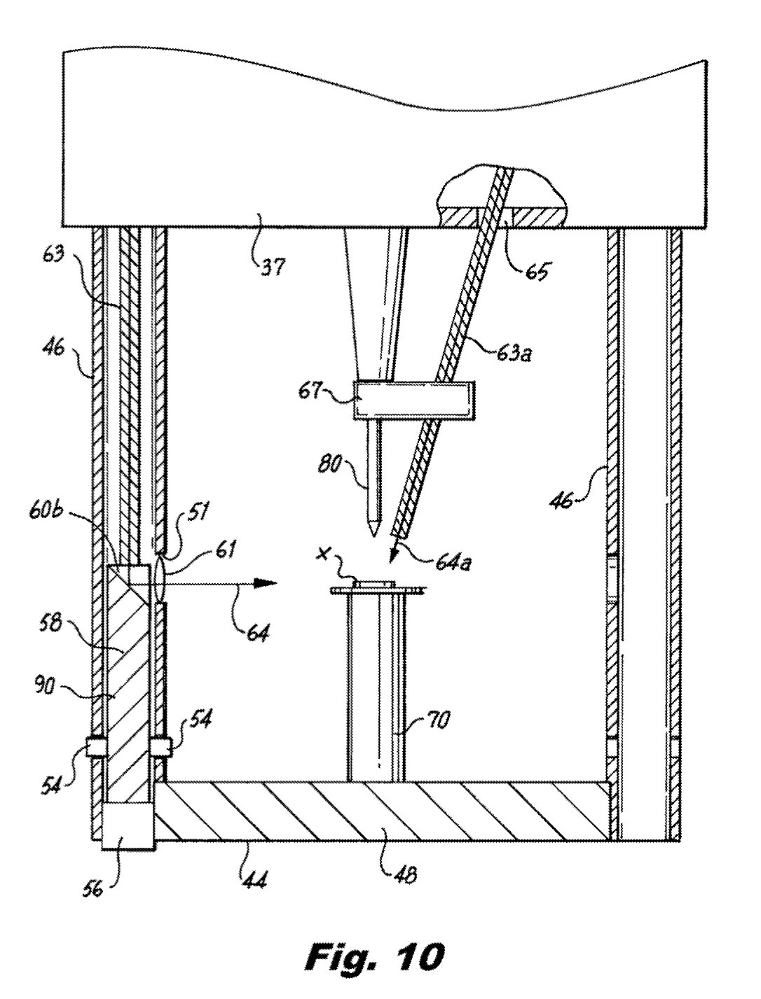

FIG. 10 shows a further modification to the present invention, wherein a STM tip 80 is used in conjunction with an optical fiber light beam delivery system. In particular, the left-hand side (as shown in FIG. 10) of the sample holder tip 44 includes an optical fiber 63 optically connected to a reflection prism 60f and further includes a convex lens 61 fixed in the light aperture 51 of the leg 46. Thus, a light beam 64 is directed to a sample X held in a sample holder structure 70, as described above. The right-hand side (as shown in FIG. 10) of the sample holder tip 44, however, has been modified to allow a second optical fiber 63a to deliver a second light beam 64 directly to the sample X. Such modification can involve removing the optical fiber 63a from the right leg 46 of the sample holder tip and feeding the optical fiber through an optical fiber aperture 65 at the distal end of the sample holder body probe portion 37, which allows the optical fiber to be positioned adjacent the STM tip 80 to deliver a light beam 64a directly to the sample X.

The optical fiber 63a can be positioned so that the light beam 64a can be delivered to the sample X at any desired angle. The optical fiber 63a can be fixed to the STM tip via a clamp or coupling 67, which can be used as a positioning stage for the optical fiber, thus enabling the user to illuminate various parts of the sample successively without removing the stage from the microscope. Also, in a reverse set-up, the optical fiber 63a can be positioned across various parts of the light emitting sample and collect locally emitted light.

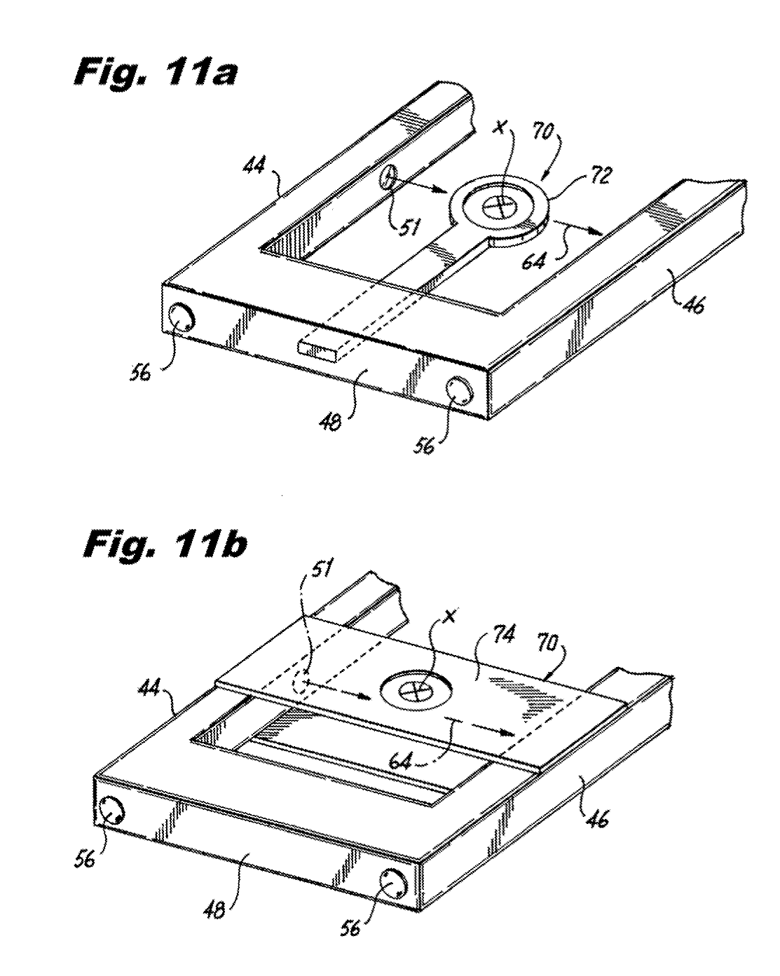

Referring now to FIGS. 9a, 10, 11a and 11b, the structure 70 for actually holding or supporting the sample X can take various forms. For example, as shown in FIG. 11a, an arm member 72 can be provided on the cross member 48 of the U-shaped body 44, which extends between and parallel with the legs 46 of the body to support a sample X between the light beam windows 51. Alternatively, as shown in FIG. 11b, a bracket assembly 74 can be removably attached to and extend between the parallel legs 46 of the U-shaped member 44 to position the sample X adjacent the light beam windows 51. In another alternative embodiment, a simple hole can be formed through the end of the cross member 48 and a wire having a sample fixed thereto can be inserted and secured to the throughhole. In any event, any conventional means can be implemented to retain the sample X within the sample retaining structure 70.

Thus, the invention is a specific type of sample holder, wherein two deflection systems can be implemented along the optical path of a light beam. Depending on the particular setup, the beam can be only deflected or deflected and focused. Each deflection system is independent and can consist of: 1) a deflection surface (mirror or prism); 2) a focusing device (optional); and 3) alignment screws.

The present methods involve using the sample holder in various analytical techniques and experimental procedures. For example, the present sample holder 10 can be used in time resolved imaging, spectroscopy and diffraction techniques whereby light is used to excite or examine a sample in the sample holder through channels of the sample holder, (as discussed above), and a secondary excitation or probe is used at some other time, provided by and within the instrument into which the sample holder is introduced, thereby providing a stroboscopic method of examining the duration and nature of responses of samples to multiple stimuli.

For example, in Zewail, “Four-Dimensional Electron Microscopy” Science, Vol. 328, pp 187-193 (Apr. 9, 2010), various techniques in four-dimensional ultrafast electron microscopy (4D UEM) are described for time resolved imaging of samples. In UEM space-time domains, images are obtained stroboscopically with single-electron coherent packets. Under such a condition, electron repulsion is absent, permitting real-space imaging, Fourier-space diffraction, and energy-space electron spectroscopy with high spatiotemporal resolutions. The time resolution becomes limited only by the laser pulse width and energy width of the packets, the camera rate of recording becomes irrelevant for the temporal resolution, and the delay between pulses can be controlled to allow for the cooling of the specimen and/or repetitiveness of the specimen's exposure.

Since its original use in viewing rotating objects, a stroboscope can produce, with appropriately chosen pulses of light, a well-resolved image of a moving object, such as a bullet or a falling apple. Thus, the pulse duration plays the same role as the opening of a camera shutter. The concept of single-electron imaging is based on the premise that trajectories of coherent and timed single-electron packets can provide an image that is equivalent to that obtained by using many electrons in conventional microscopes. When a sufficient number of such clicks are accumulated stroboscopically, the whole image emerges.

In the microscope, the electron pulse that produces the image is termed the probe pulse. To visualize the motion, the molecule or material must be launched on its path by using a femtosecond initiation optical pulse, called the pump pulse or clocking pulse, thus establishing a temporal reference point (time zero) for the changes that occur in the motion. By sending the pump pulse along an adjustable optical path, one can precisely fix each probe frame on the time axis.

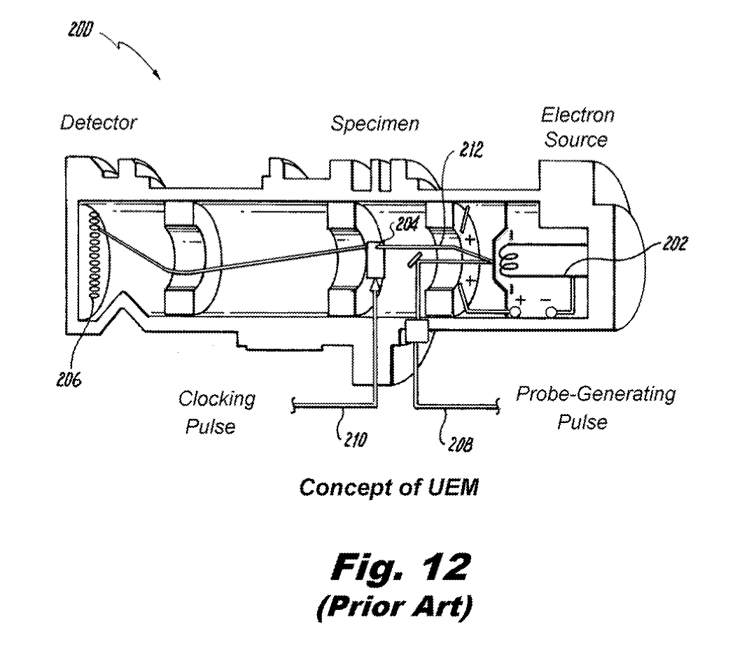

FIG. 12 shows a conventional ultrafast electron microscope (UEM) 200 of the prior art. The UEM 200 generally includes an electron source 202, a specimen support 204 and a detector 206.

A first light beam 210, termed a “pump pulse” or a “clocking pulse” is introduced into the device 200 from an external source and is directed toward the specimen. In the meantime, a second light beam 208, termed a “probe-generating pulse” is introduced into the device 200 from an external source and is directed toward the electron source 202. The second light beam 208 may be a photon pulse for exciting the electrons of the electron source. Interaction of the second light beam 208 with the electron source 202 causes the electron source to emit a probe pulse 212, in this case, an electron pulse, which is directed to the specimen, where it converges with the pump pulse of the first light beam. The detector 206 detects the resultant probe pulse 212. In this manner, the specimen can be analyzed under the conditions of the converging energy pulse and the pump pulse.

Upon the initiation of the structural change of the specimen by heating, or through electronic excitation by an ultra-short pump pulse, a series of frames for real-space images, and similarly for diffraction patterns or electron energy-loss spectra (EELS), can be obtained. In the single-electron mode of operation, which affords studies of reversible processes or repeatable exposures, the train of strobing electron pulses is used to build up the image.

However, as can be appreciated, the introduction of light beams from external sources into a device maintained under strict vacuum conditions can be challenging. Moreover, the minimal space limitations inherent with such devices add to the difficulty of performing such time-resolved imaging.

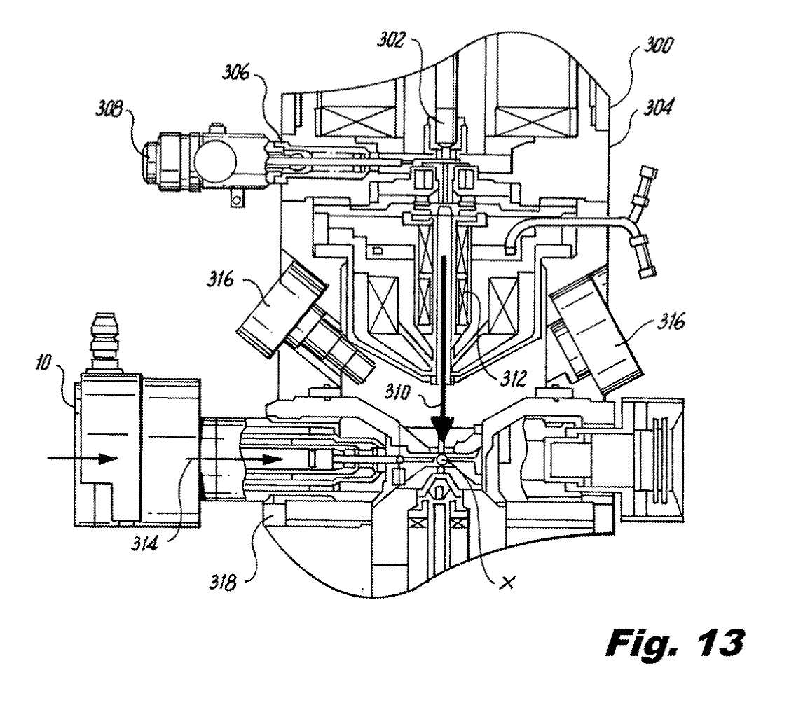

The present sample holder solves these problems by providing both a means for supporting the sample within an analytical device as well as a conduit for the first light beam functioning as the pump pulse. More specifically, as shown in FIG. 13, the present sample holder 10 is shown installed at a first access port of an analytical device 300 having an energy source 302 contained within a device housing 304.

As described in detail above, the sample holder 10 has features which enable it to convey a light beam 314, termed a “pump pulse” or a “clocking pulse,” through an internal conduit of the sample holder body and to direct the light beam between the sample holder body and the sample X with a first light beam positioner of the sample support member. The light beam 314 and an energy pulse 310, supplied by the energy source 302, will thus converge on the sample X and the resultant energy pulse can be analyzed under such conditions.

The energy source 302 can be an electron source contained within the housing 304, as described above with respect to the ultra-fast electron microscope, in which case an external photon probe-generating pulse is used to excite the electrons. However, other energy sources, such as neutron sources, x-ray sources, etc, can be contained within the device housing 304 for emitting energy pulses that are not dependent on external photon excitation. In such cases, the energy pulse is supplied by the energy source itself, without the need for a probe pulse.

In still other embodiments, an external energy source provided outside the device housing can be used. For example, instead of providing the probe-generating pulse to an internal energy source, an external light source can be provided, which emits an energy pulse, or probe pulse of photons directly at the sample.

In applications involving a photon excitable energy source 302 contained within the device housing 304, a second access port 306 is provided in the device housing and an external second light source 308 is provided at the second access port. The second access port 306 and the second light source 308 are positioned relative to the energy source 302 such that a second light beam, also termed a “probe-generating pulse,” emitted by the second light source will be directed at the energy source supported within the housing of the analytical device. In a known manner, the energy source 302 will emit an energy pulse 310 in response to the interaction of the second light beam with the energy source. The energy pulse 310, also termed a “probe pulse,” is directed toward a sample X held by the sample holder 10 of the present invention. In this regard, the analytical device 300 will typically include an arrangement of electromagnetic lenses 312 contained within the housing 304 for directing and focusing the energy pulse 310 through the sample X to be analyzed by a detector or camera (not shown) downstream of the sample.

As can be appreciated, by conveying the first light beam (pump pulse) through the sample holder, an additional access port in the device housing for a first external light source is not required. Thus, efficient use can be made of the minimal space within the analytical device. This will allow, for example, the use of additional measuring or sensing devices 316 provided on the device 300, which would not be possible without the sample holder 10 of the present invention.

As mentioned above, the sample holder 10 of the present invention can be used in a four-dimensional ultra-fast electron microscope. In this case, the energy source 302 shown in FIG. 13 would be an electron emitter and the energy pulse 310 would be a pulse of electrons. As also mentioned above, it is conceivable that other analytical devices having energy sources such as neutron emitters, photon emitters, x-ray emitters, etc. can also be utilized in conjunction with the present invention.

For example, photoelectrons, which may be invoked in diffraction studies of a sample, provide the means to reach much higher time resolution, assuming that the photoelectrons generated by an optical pulse do not suffer from temporal and spatial losses of resolution during the journey to the specimen and on to the detector. To study single particles (sites) of nanoscale with UEM, 4D nanodiffraction imaging of structural dynamics with convergent electron (pulsed) beams can be utilized. Instead of using a parallel electron-beam illumination with a single-electron wave vector, a convergent beam (CB) with a span of incident wave vectors is focused on the specimen.

Another variant UEM technique is 4D tomography, in which electron pulses, for a given beam focus and at a fixed time delay, give rise to images for a whole series of tilt angles. When this process is repeated for a sequence of time delays on the femtosecond and nanosecond timescales, a 4D tomograph is constructed.

The present sample holder 10 of the present invention also provides a convenient means for retrofitting an analytical device 300 to perform time resolved imaging, spectroscopy, or diffraction techniques involving a sample X, where the analytical device already has an energy source 302 for emitting an energy pulse 310 at the sample. The analytical device can be easily modified by providing a first access port 318 in the housing 304 of the analytical device 300 for inserting the sample holder 10 of the present invention. A second access port 306 may also be provided in the analytical device for providing optical access to the energy source 302 from outside the analytical device. A second light beam source 308 is then situated at the second access port for directing a first light beam at the energy source 302.

The sample holder 10 has all of the features described above, including an external alignment part for directing a first light beam in a predetermined beam direction, a sample holder body in optical communication with the external aligmnent part and defining an internal conduit for conveying the first light beam and a sample support member disposed at a distal end of the sample holder body opposite the external alignment part for holding the sample to be analyzed. The sample support member includes a first light beam positioner for directing the first light beam between the sample holder body and the sample X held by the sample support member.

As a result of the present invention, a sample holder is provided, which, for the first time, integrates independent measurement systems in one setup that enables simultaneous measurement of geometric, electric, electronic and optical properties of materials in a very small space.

Thus, owing to its extremely compact nature and suite of features, the sample holder of the present invention is well suited to accomplish the tasks outlined above in a variety of analytical instruments where optical access to the sample from outside the instrument and the sample holder is required or other methods of introducing and collecting light do not present themselves. These techniques include, but are not limited to, those microscopies or other probes whose measuring elements require a very short working distance between themselves and a sample. Examples of such instruments in which the sample holder of the present invention may be employed include TEMs, scanning tunneling microscopes, scanning electron microscopes, (including those utilizing backscattered or secondary electrons), optical microscopes, atomic force microscopes, helium ion microscopes, photoelectron microscopes, x-ray microscopes and other systems in which a vacuum compatible sample holder with optical features is to be used, such as in neutron scattering and synchrotron radiation facilities.

Although the illustrative embodiments of the present invention have been described herein with reference to the accompanying drawings, it is to be understood that the invention is not limited to those precise embodiments, and that various other changes and modifications may be effected therein by one skilled in the art without departing from the scope or spirit of the invention. For example, it is conceivable that the STM tip can be replaced with a cooling system for changing the local temperature at the sample position, as shown in FIG. 9.

Various changes to the foregoing described and shown structures will now be evident to those skilled in the art. Accordingly, the particularly disclosed scope of the invention is set forth in the following claims.

1. A method for performing time resolved imaging, spectroscopy or diffraction techniques involving a sample held in an analytical device, the method comprising:
supporting a sample within an analytical device with a sample holder, the sample holder having a sample holder body extending within an interior of the analytical device and a sample support member disposed at a distal end of the sample holder body for supporting the sample;
directing an energy pulse at the sample held in the sample holder;
conveying a first light beam through an internal conduit of the sample holder body of the sample holder;
directing the first light beam between the sample holder body and the sample with a first light beam positioner of the sample support member, such that the first light beam and the energy pulse converge on the sample; and
analyzing the sample under conditions of the converging energy pulse and the first light beam.

2. A method as defined in claim 1, further comprising:
directing a second light beam at an energy source provided within the analytical device; and
emitting the energy pulse from said energy source in response to the energy source receiving the second light beam.

3. A method as defined in claim 2, wherein the analytical device is a four-dimensional ultra-fast electron microscope and the energy source is an electron emitter.

4. A method as defined in claim 1, further comprising varying a time duration between the first light beam and the energy pulse to perform time resolved imaging of the sample.

5. A method as defined in claim 1, further comprising repeating directing the first light beam at the sample and directing the energy pulse at the sample to perform stroboscopic time resolved imaging of the sample.

6. A method as defined in claim 1, wherein the first light beam travels from the sample holder body and is deflected by the first light positioner toward the sample.

7. A method as defined in claim 6, wherein the first light beam further travels from the sample and is deflected back to the sample holder body by a second light positioner of the sample support member.

8. A method as defined in claim 1, wherein the first light beam travels from the sample and is deflected by the first light positioner into the sample holder body.

9. A method as defined in claim 1, further comprising directing a second light beam between the sample holder body and the sample with a second light positioner of the sample support member.

10. A method as defined in claim 1, wherein the first light beam is conveyed through the sample holder body via an optic fiber disposed within the internal conduit of the sample holder body.

11. A method for retrofitting an analytical device to perform time resolved imaging, spectroscopy, or diffraction techniques involving a sample, the analytical device having an energy source for emitting an energy pulse at the sample, the method comprising:
providing a first access port in the analytical device for inserting a sample into the analytical device;
inserting a sample holder in said first access port of the analytical device, said sample holder comprising:
an external alignment part for directing a first light beam in a predetermined beam direction;
a sample holder body in optical communication with said external alignment part, said sample holder body defining an internal conduit for conveying the first light beam; and
a sample support member disposed at a distal end of said sample holder body opposite said external alignment part for holding the sample to be analyzed, said sample support member including a first light beam positioner for directing the first light beam between said sample holder body and a sample held by said sample support member; and
providing an analyzer for analyzing the sample under conditions of the energy pulse and the first light beam converging on the sample.

12. A method as defined in claim 11, further comprising
providing a second access port in the analytical device for providing optical access to the energy source from outside the analytical device;
providing a second light beam source at said access port for directing a second light beam at the energy source.

13. A method as defined in claim 11, wherein the analytical device is a four-dimensional ultra-fast electron microscope and the energy source is an electron emitter.

14. A method as defined in claim 11, wherein the first light beam is provided by a light source provided outside the analytical device.

15. A method as defined in claim 11, wherein the sample support member of the sample holder further comprises a second light beam positioner, said first light beam positioner delivering the first light beam from said sample holder body to the sample held by the sample support member and said second light beam positioner collecting the first light beam from the sample and delivering the first light beam to said sample holder body.

16. A method as defined in claim 11, wherein said first light positioner of the sample holder is a light deflection assembly for deflecting the first light beam to and/or from the sample held by said sample support member.

17. A method as defined in claim 16, wherein said light deflection assembly comprises:
a mirror support;
a mirror disposed at a distal end of said mirror support;
a first adjustment mechanism provided at a proximal end of said mirror support opposite said mirror for positioning said mirror in a first direction;
a second adjustment mechanism engaged with said mirror support for positioning said mirror in a second direction; and
a third adjustment mechanism engaged with said mirror support for positioning said mirror in a third direction.

18. A method as defined in claim 11, wherein said sample support member of said sample holder comprises a U-shaped body including parallel legs joined by a cross member, said legs being fixed to said sample holder body and at least one of said legs having an axial bore communicating with said internal conduit of said sample holder body for conveying the first light beam between said sample holder body and said sample.

19. A method as defined in claim 18, wherein said at least one leg further includes a transverse window communicating with said axial bore in said leg, and wherein said first light positioner is a light deflection assembly disposed in said axial bore of said leg adjacent said window for deflecting the first light beam between said leg axial bore and the sample through said window.

20. A method as defined in claim 11, wherein the sample holder further comprises at least one optical fiber disposed within said internal conduit of said sample holder body for conveying the first light beam.

21. A method as defined in claim 20, wherein said light beam positioner comprises a support platform, said support platform retaining said optical fiber and being adjustable with respect to said sample support member for directing the light beam to and/or from said sample.
